(19) United States
(12) Patent Application Publication
(10) Pub. No.: US 2025/0142866 A1
(43) Pub. Date: May 1, 2025

(54) SELF-ALIGNED GATE STRUCTURE

(71) Applicant: TEXAS INSTRUMENTS INCORPORATED, Dallas, TX (US)

(72) Inventors: Zhikai Tang, Sunnyvale, CA (US); Masahiko Higashi, Aizuwakamatsu (JP); Ujwal Radhakrishna, San Jose, CA (US); Jungwoo Joh, Allen, TX (US)

(21) Appl. No.: 18/783,955

(22) Filed: Jul. 25, 2024

Related U.S. Application Data
(60) Provisional application No. 63/593,961, filed on Oct. 27, 2023.

(51) Int. Cl. H01L 29/778; H01L 29/20; H01L 29/40; H01L 29/423; H01L 29/66

(52) U.S. Cl. CPC H10D 30/475; H10D 30/015; H10D 62/8503; H10D 64/111; H10D 64/411

(57) ABSTRACT

The present disclosure generally relates to semiconductor processing for a self-aligned gate structure and corresponding semiconductor device. In an example, a semiconductor device includes a semiconductor substrate, a semiconductor gate layer, an offset dielectric layer, and a gate metal contact. The semiconductor gate layer is over the semiconductor substrate. The offset dielectric layer is over the semiconductor gate layer. The gate metal contact is over the offset dielectric layer and is through an opening through the offset dielectric layer. The gate metal contact contacts the semiconductor gate layer through the opening through the offset dielectric layer. A first sidewall of the semiconductor gate layer, a second sidewall of the offset dielectric layer, and a third sidewall of the gate metal contact are vertically aligned over the semiconductor substrate.

### CROSS-REFERENCE TO RELATED APPLICATIONS

This application claims priority to and the benefit of U.S. Provisional Patent Application Ser. No. 63/593,961, filed on Oct. 27, 2023, which is incorporated herein by reference in its entirety.

### BACKGROUND

A type of semiconductor device is a high electron mobility transistor (HEMT). A HEMT typically employs different semiconductor materials to form a heterojunction, where a channel may be formed near the heterojunction and between a source and a drain. A HEMT may have a high speed operation, which makes HEMTs attractive for high frequency applications, among others.

### SUMMARY

An example described herein is a semiconductor device. The semiconductor device includes a semiconductor substrate, a semiconductor gate layer, an offset dielectric layer, and a gate metal contact. The semiconductor gate layer is over the semiconductor substrate. The offset dielectric layer is over the semiconductor gate layer. The gate metal contact is over the offset dielectric layer and is through an opening through the offset dielectric layer. The gate metal contact contacts the semiconductor gate layer through the opening through the offset dielectric layer. A first sidewall of the semiconductor gate layer, a second sidewall of the offset dielectric layer, and a third sidewall of the gate metal contact are vertically aligned over the semiconductor substrate.

Another example is a semiconductor device. The semiconductor device includes a high electron mobility transistor (HEMT) on a semiconductor substrate. The HEMT includes a semiconductor gate layer, an offset dielectric layer, and a gate metal contact. The semiconductor gate layer is over a barrier layer over the semiconductor substrate. The offset dielectric layer is over the semiconductor gate layer. The offset dielectric layer has an opening to the semiconductor gate layer. The gate metal contact is on the offset dielectric layer and is in the opening contacting the semiconductor gate layer. A first sidewall of the semiconductor gate layer, a second sidewall of the offset dielectric layer, and a third sidewall of the gate metal contact are vertically aligned over the semiconductor substrate.

A further example is a method. A semiconductor gate layer is formed over a semiconductor substrate. An offset dielectric layer is formed over the semiconductor gate layer. The offset dielectric layer has an opening exposing the semiconductor gate layer. A gate metal contact layer is formed over the offset dielectric layer and on the semiconductor gate layer through the opening. After forming the gate metal contact layer, the gate metal contact layer, the offset dielectric layer, and the semiconductor gate layer are patterned.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a cross-sectional view of a semiconductor device according to some examples.

FIG. 2 is a cross-sectional view of a semiconductor device according to some examples.

FIGS. 3, 4, 5, 6, 7, 8, and 9 are respective cross-sectional views of a semiconductor device in intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for a self-aligned gate structure and corresponding semiconductor device, such as for a high electron mobility transistor (HEMT). Generally, a semiconductor device includes a semiconductor gate layer, an offset dielectric layer, and a gate metal contact. The semiconductor gate layer is over a semiconductor substrate. The offset dielectric layer is over the semiconductor gate layer. The gate metal contact is over the offset dielectric layer and extends through an opening through the offset dielectric layer. The gate metal contact contacts the semiconductor gate layer through the opening through the offset dielectric layer. Respective sidewalls of the semiconductor gate layer, the offset dielectric layer, and the gate metal contact are vertically aligned over the semiconductor substrate. Generally, the semiconductor gate layer may be formed over the semiconductor substrate, and the offset dielectric layer may be formed over the semiconductor gate layer. An opening may be formed through the offset dielectric layer, which exposes the semiconductor layer. A gate metal contact layer may be formed over the offset dielectric layer and in the opening, thus contacting the semiconductor gate layer through the opening. The gate metal contact layer, the offset dielectric layer, and the gate layer may be patterned together, such as by using a single photomask.

Examples described herein may avoid formation of a metal stringer on a passivation or dielectric layer at a sidewall of a gate layer that may be formed by other processes. Additionally and/or alternatively, over-etching damage to the passivation or dielectric layer, which may occur when removing the metal stringer, may be obviated. This may improve yield in fabricating semiconductor devices and improve reliability of the semiconductor devices. Compared to still other processes, examples described herein may avoid etch induced damage to surfaces of a semiconductor gate layer, which may result in lower gate leakage. Further, fewer photolithography processes (which may require fewer photomasks) may be necessary to fabricate the semiconductor devices, which may reduce fabrication costs. Other benefits and advantages may be achieved.

Various examples are described subsequently. Although the specific examples may illustrate various aspects of the above generally described features, examples may incorporate any combination of the above generally described features (which are described in more detail in examples below).

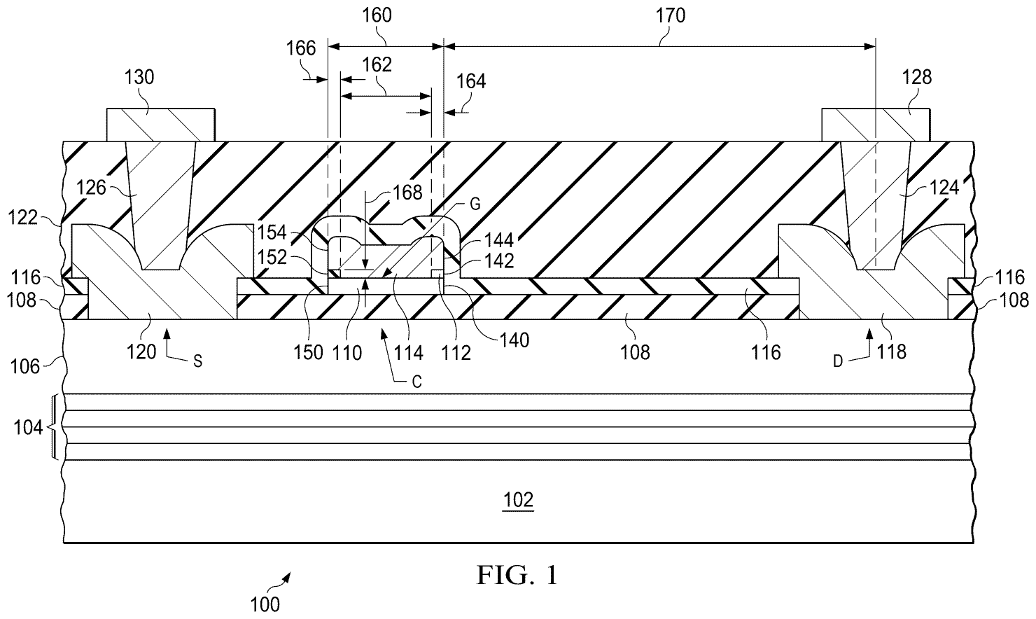

FIG. 1 illustrates a cross-sectional view of a semiconductor device 100 according to some examples. The semiconductor device 100, in this example, is or includes an enhancement mode (Emode) HEMT. The semiconductor device 100 may be rated for a low voltage (LV) application (e.g., equal to or less than 100 V), a medium voltage (MV) application (e.g., in a range from 100 V to 300 V), or a high voltage (HV) application (e.g., equal to or greater than 400 V, and more particularly, equal to or greater than 600 V). A LV, MV, or HV application rating of a semiconductor device does not indicate a particular threshold voltage for that semiconductor device. A semiconductor device rated for a HV application may have a magnitude of the threshold voltage that is low. Conversely, a semiconductor device rated for a LV application may have a magnitude of a threshold voltage that is high. A voltage rating may be based on, at least in part, a lateral distance between drain region and a gate structure.

FIG. 1 shows a semiconductor substrate 102 and one or more transition layers 104 over and on the semiconductor substrate 102. A channel layer 106 is over and on the uppermost transition layer 104. A barrier layer 108 is over and on the channel layer 106. In some examples, the semiconductor substrate 102, transition layer(s) 104, channel layer 106, and barrier layer 108 may together be considered a semiconductor substrate.

The semiconductor substrate 102 may be a bulk semiconductor substrate, a semiconductor-on-insulator (SOI) substrate, or any other appropriate substrate. For example, the semiconductor substrate 102 may be or include a bulk silicon wafer. The transition layer(s) 104 may include any number of layers of any materials that are configured to accommodate lattice mismatch between the semiconductor substrate 102 and the channel layer 106 (e.g., to reduce or minimize lattice defect generation and/or propagation in the channel layer 106). For example, the transition layer(s) 104 may have a gradient concentration of one or more elements in a direction normal to the upper surface of the semiconductor substrate 102. Further, a layer of the transition layer(s) 104 may be a doped buffer layer.

The channel layer 106 is configured, possibly in conjunction with the barrier layer 108, to conduct and confine charge carriers (such as electrons) within two dimensions. In some examples, the channel layer 106 is configured to include a two-dimensional electron gas (2DEG). The 2DEG may be formed by energy band bending resulting from the barrier layer 108 being over and on the channel layer 106. In some examples, the channel layer 106 may be a portion of a semiconductor substrate (e.g., without transition layer(s)), and/or the semiconductor substrate 102 with the transition layer(s) 104 and the channel layer 106 may be considered a semiconductor substrate. In some examples, the channel layer 106 includes a gallium nitride (GaN) layer and, in such examples, may be referred to as a GaN channel layer. In some examples, the material of the channel layer 106 is or includes an unintentionally doped material, such as a material doped by diffusion of dopants from another layer, or is or includes an intrinsic material. The barrier layer 108, in some examples, may be or include an aluminum gallium nitride (AlGaN) layer and, in such examples, may be referred to as an AlGaN barrier layer. In some examples, the channel layer 106 may be or include indium aluminum gallium nitride (InᵢAlⱼGa₁₋ᵢ₋ⱼN) (where 0≤i≤1, 0≤j≤1, and 0≤i+j≤1), and the barrier layer 108 may be or include indium aluminum gallium nitride (InₖAlₗGa₁₋ₖ₋ₗN) (where 0≤k≤1, 0≤l≤1, and 0≤k+l≤1). Other materials may be implemented for the channel layer 106 and/or the barrier layer 108.

A gate layer 110 is over and on an upper surface of the barrier layer 108. In some examples, the gate layer 110 is or includes a semiconductor layer of a semiconductor material. Further, in some examples, the gate layer 110 is doped with a dopant. In some examples, the gate layer 110 is doped with a p-type dopant. In some examples, the gate layer 110 may be or include a gallium nitride (GaN) layer, such as indium aluminum gallium nitride (InₘAlₙGa₁₋ₘ₋ₙN) (where 0≤m<1, 0≤n<1, and 0≤m+n≤1), and the dopant with which the gate layer 110 is doped is a p-type dopant, which may be or include magnesium (Mg), carbon (C), zinc (Zn), the like, or a combination thereof. In examples in which the gate layer 110 is gallium nitride (GaN) doped with a p-type dopant, the gate layer 110 may be referred to as a p-doped GaN (pGaN) layer. Further, in examples in which the gate layer 110 is gallium nitride (GaN) doped with a magnesium, the gate layer 110 may be referred to as a magnesium doped gallium nitride (GaN:Mg) layer. In some examples, a concentration of the dopant in the gate layer 110, which is electrically activated, is equal to or greater than 1×10¹⁷ cm⁻³. In some examples, the concentration is equal to or greater than 1×10¹⁸ cm⁻³. In some examples, the dopant in the gate layer 110 may have a uniform concentration. In some examples, the dopant in the gate layer 110 may have a gradient concentration. Other materials, dopants, and/or concentrations may be implemented in other examples.

An offset dielectric layer 112 is over and on an upper surface of the gate layer 110. The offset dielectric layer 112 may be or include silicon nitride, silicon oxide, another dielectric material, or the like. The offset dielectric layer 112 is at lateral peripheries of the gate layer 110, as described in more detail subsequently.

A gate metal contact 114 extends through the offset dielectric layer 112 and contacts the gate layer 110. The gate metal contact 114 is over and on the offset dielectric layer 112 at the lateral peripheries of the gate layer 110. The gate metal contact 114 may include or be any appropriate metal. In some semiconductor devices, the gate metal contact 114 may form a Schottky junction with the gate layer 110. As examples, when the gate layer 110 is magnesium doped gallium nitride (GaN:Mg), metal that may form a Schottky junction with the gate layer 110 may be or include titanium (Ti), titanium tungsten (TiW), titanium nitride (TiN), nickel (Ni), platinum (Pt), tantalum nitride (TaN), copper (Cu), tungsten (W), or alloys thereof. In some semiconductor devices, the gate metal contact 114 may form an ohmic junction with the gate layer 110. As examples, when the gate layer 110 is magnesium doped gallium nitride (GaN:Mg), metal that may form an ohmic junction with the gate layer 110 may be or include gold (Au), nickel (Ni), aluminum (Al), or alloys thereof, which alloys may include titanium tungsten aluminum (TiWAl) and titanium aluminum nitride (TiAlN). In some examples, the gate metal contact 114 includes a first portion including a metal that forms a Schottky junction with the gate layer 110 and a second portion including a metal that forms an ohmic junction with the gate layer 110, such as described in U.S. patent application Ser. No. 18/361,997, filed Jul. 31, 2023, which is incorporated by reference herein in its entirety.

The gate layer 110, offset dielectric layer 112, and gate metal contact 114 have vertically aligned outer sidewalls. On a drain side, a sidewall 140 of the gate layer 110, an outer sidewall 142 of the offset dielectric layer 112, and a sidewall 144 of the gate metal contact 114 are vertically aligned. On a source side, a sidewall 150 of the gate layer 110, an outer sidewall 152 of the offset dielectric layer 112, and a sidewall 154 of the gate metal contact 114 are vertically aligned. An outer lateral dimension 160 (e.g., a gate length) is between the sidewalls 140, 150 of the gate layer 110, and hence, is also between the outer sidewalls 142, 152 of the offset dielectric layer 112 and between the sidewalls 144, 154 of the gate metal contact 114. The offset dielectric layer 112 has an opening with an inner lateral dimension 162 through which the gate metal contact 114 contacts the gate layer 110. The offset dielectric layer 112 has a first offset lateral dimension 164 from the outer sidewall 142 of the offset dielectric layer 112 to a corresponding (e.g., nearest) sidewall of an opening through the offset dielectric layer 112 and has a second offset lateral dimension 166 from the outer sidewall 152 of the offset dielectric layer 112 to a corresponding (e.g., nearest) sidewall of the opening through the offset dielectric layer 112. In some examples, the offset lateral dimensions 164, 166 may be equal, but in some examples, the offset lateral dimensions 164, 166 may be unequal (e.g., due to misalignment of photomasks or device design optimization). The outer lateral dimension 160 (e.g., gate length) is equal to the sum of the inner lateral dimension 162, the first offset lateral dimension 164, and the second offset lateral dimension 166. The lateral dimensions 160-166 are parallel to a direction from a drain region D to a source region S, which are described more subsequently.

In some examples, each of the first offset lateral dimension 164 and the second offset lateral dimension 166 may be greater than or equal to 2% of the outer lateral dimension 160, may be less than or equal to 40% of the outer lateral dimension 160, or may be in a range from 2% to 40% of the outer lateral dimension 160. In some examples, the inner lateral dimension 162 may be greater than or equal to 30% of the outer lateral dimension 160, may be less than or equal to 95% of the outer lateral dimension 160, or may be in a range from 30% to 95% of the outer lateral dimension 160. In some examples, each of the first offset lateral dimension 164 and the second offset lateral dimension 166 may each be in a range from 10 nm to 500 nm, and the outer lateral dimension 160 may be in a range from 100 nm to 3,000 nm.

More specifically, for a LV application for example, each of the first offset lateral dimension 164 and the second offset lateral dimension 166 may be in a range from 10 nm to 200 nm, and the outer lateral dimension 160 may be in a range from 150 nm to 400 nm. For a MV application for example, each of the first offset lateral dimension 164 and the second offset lateral dimension 166 may be in a range from 60 nm to 500 nm, and the outer lateral dimension 160 may be in a range from 400 nm to 1.7 μm. For a HV application for example, each of the first offset lateral dimension 164 and the second offset lateral dimension 166 may be in a range from 200 nm to 500 nm, and the outer lateral dimension 160 may be in a range from 1.7 μm to 3 μm.

Additionally, the offset dielectric layer 112 has a thickness 168, which may be in a range from 5 nm to 1,000 nm. More specifically, for a LV application for example, the thickness 168 may be in a range from 5 nm to 100 nm. For a MV application for example, the thickness 168 may be in a range from 5 nm to 200 nm. For a HV application for example, the thickness 168 may be in a range from 10 nm to 1,000 nm.

A passivation layer 116 is conformally over and on the upper surface of the barrier layer 108, on and along the sidewalls 140, 150, 142, 152, 144, 154 of the gate layer 110, the offset dielectric layer 112, and the gate metal contact 114, and over and on an upper surface of the gate metal contact 114. In some examples, the passivation layer 116 may be or include silicon nitride, silicon oxide, silicon oxynitride, aluminum oxide (Al₂O₃), aluminum nitride (AlN), aluminum oxynitride (AlON), hafnium oxide (HfO₂), any other dielectric material, or a combination thereof. In some examples, a regrowth barrier layer may be over and on the gate metal contact 114, and the passivation layer 116 may be over and on the regrowth barrier layer. In such examples, the regrowth barrier layer may be or include an aluminum gallium nitride (AlGaN) layer.

A drain metal contact 118 and a source metal contact 120 extend through the passivation layer 116 and the barrier layer 108 and contact the channel layer 106. In some examples, the drain metal contact 118 and source metal contact 120 do not extend through the barrier layer 108, and may contact an upper surface of the barrier layer 108 or extend into the barrier layer 108. In some examples, the drain metal contact 118 and source metal contact 120 may be or include a metal that forms an ohmic junction with the channel layer 106 and/or barrier layer 108. The drain metal contact 118 and source metal contact 120 may be or include metal, such as titanium nitride (TiN), tantalum nitride (TaN), titanium (Ti), aluminum (Al), copper (Cu), tungsten (W), the like, or a combination thereof.

A dielectric layer 122, which may be an inter-layer dielectric layer (ILD), is over and on the passivation layer 116 and the metal contacts 118, 120. The dielectric layer 122 may be a single dielectric layer or may include multiple dielectric layers of a same dielectric material or different dielectric materials. For example, the dielectric layer 122 may include silicon nitride, a silicon oxide-based material (such as a phosphosilicate glass (PSG) or a tetraethyl orthosilicate (TEOS) oxide), polytetrafluoroethylene, or the like.

Metal vias 124, 126 are through the dielectric layer 122. Metal via 124 contacts the drain metal contact 118. Metal via 126 contacts the source metal contact 120. Metal lines 128, 130 are over and on the dielectric layer 122. Metal line 128 is further over and on (and electrically connected to) the metal via 124. Metal line 130 is further over and on (and electrically connected to) the metal via 126. The metal vias 124, 126 may each include (i) one or more metal-barrier and/or adhesion layers (e.g., titanium nitride (TiN), tantalum nitride (TaN), the like, or a combination thereof) conformally in a respective opening through the dielectric layer 122 and (ii) a fill metal (e.g., aluminum (Al), copper (Cu), tungsten (W), the like, or a combination thereof) over and/or on the metal-barrier and/or adhesion layer(s). The metal lines 128, 130 may each include one or more metal-barrier and/or adhesion layers (e.g., titanium nitride (TiN), tantalum nitride (TaN), the like, or a combination thereof) and a bulk metal (e.g., aluminum (Al), copper (Cu), the like, or a combination thereof) over and/or on the metal-barrier and/or adhesion layer(s).

The semiconductor device 100 has a gate-to-drain lateral dimension 170. The gate-to-drain lateral dimension 170 is from the sidewall 140 of the gate layer 110 to a center of the drain metal contact 118 and is parallel to the direction from the drain region D to the source region S. In some examples, for a LV application, the gate-to-drain lateral dimension 170 is in a range from 0.1 μm to 1 μm. In some examples, for a MV application, the gate-to-drain lateral dimension 170 is in a range from 1 μm to 10 μm. In some examples, for a HV application, the gate-to-drain lateral dimension 170 is in a range from 10 μm to 100 μm.

The semiconductor device 100 includes a source region S, a channel region C, a drain region D, and a gate terminal G. The gate terminal G is or includes the gate layer 110. The channel region C is in the channel layer 106 underlying the gate terminal G. The channel region C is laterally between the drain region D and the source region S, which are also in the channel layer 106. The drain metal contact 118 is electrically coupled to the drain region D, and the source metal contact 120 is electrically coupled to the source region S. The gate metal contact 114 is electrically coupled to the gate terminal G (e.g., the gate layer 110). The gate terminal G and gate metal contact 114 are laterally between the drain metal contact 118 and the source metal contact 120.

Generally, at smaller device dimensions (e.g., as the semiconductor device 100 is scaled to smaller sizes), an electric field may increase between the gate layer 110 and the source region S and between the gate layer 110 and the drain region D. In the absence of the offset dielectric layer 112, forward gate leakage may occur at the lateral periphery (e.g., at sidewalls) of the gate layer 110 due to the increased electric field. The offset dielectric layer 112 may be an isolation that breaks a direct conductive path at the periphery of the gate layer 110 from the gate metal contact 114, which may reduce gate forward leakage and also increase a gate forward breakdown voltage.

The offset lateral dimensions 164, 166 of the offset dielectric layer 112 may be determined based on a target performance of the semiconductor device 100. For a given outer lateral dimension 160, increasing the offset lateral dimensions 164, 166 results in decreasing the inner lateral dimension 162. Too small of an inner lateral dimension 162 may increase a gate resistance (R_{G}) and reduce gate control. With a smaller inner lateral dimension 162, less capacitance coupling from the gate metal contact 114 to the channel region C occurs to control the channel region C and turn the semiconductor device 100 on, which also increases the drain-to-source on resistance (R_{DSON}). Also, the saturation current capability of the semiconductor device 100 may be decreased. Hence, the offset lateral dimensions 164, 166 of the offset dielectric layer 112 may be implemented in a way to balance (i) reducing gate forward leakage and increasing gate forward breakdown voltage and (ii) increasing R_{G} and R_{DSON} and decreasing saturation current capability.

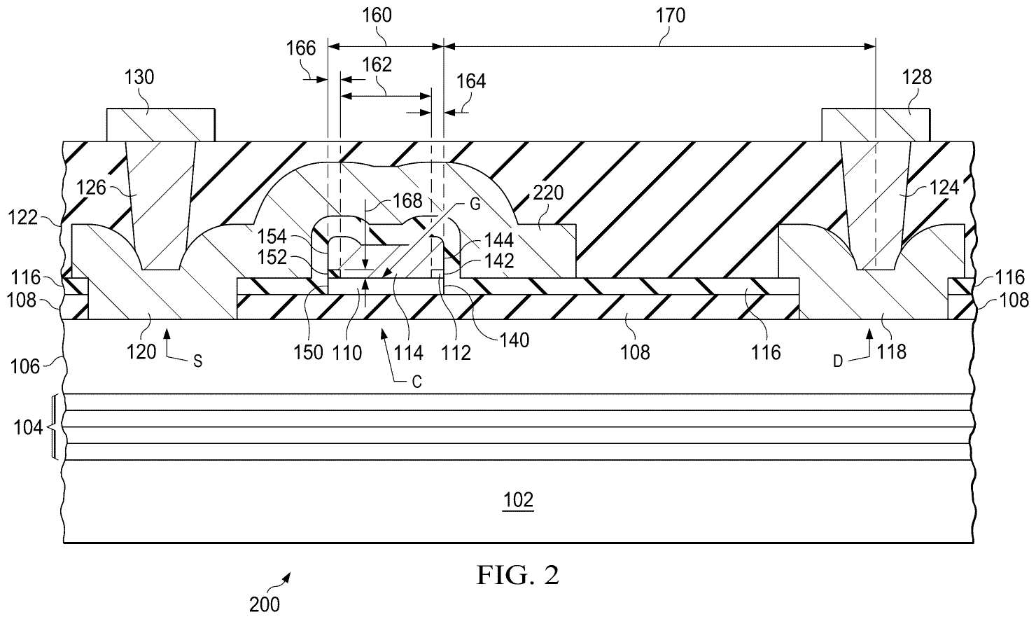

FIG. 2 illustrates a cross-sectional view of a semiconductor device 200 according to some examples. The semiconductor device 200 of FIG. 2 is generally like the semiconductor device 100 of FIG. 1 and includes a source-coupled field plate 220. The source-coupled field plate 220 is over the passivation layer 116 and gate metal contact 114 and extends laterally from the gate metal contact 114 and gate layer 110 towards the drain metal contact 118 and/or the drain region D. In the illustrated example, the source metal contact 120 and the source-coupled field plate 220 are an integral piece of metal(s) such that the source-coupled field plate 220 is electrically connected to the source region S. In other examples, the source metal contact 120 and the source-coupled field plate 220 may be separate components and may be electrically connected through other metal layers. Various other field plates and configurations of field plates may be implemented in other examples. For example, multiple field plates may be implemented. Field plates may be electrically coupled or connected to the gate layer 110 and/or gate metal contact 114 and to the source metal contact 120. Field plates may be substantially horizontal or sloped. Different configurations of field plate(s) may be implemented to manage an electric field between the gate layer 110 and the channel layer 106. The source-coupled field plate 220 of FIG. 2 is illustrated merely as an example.

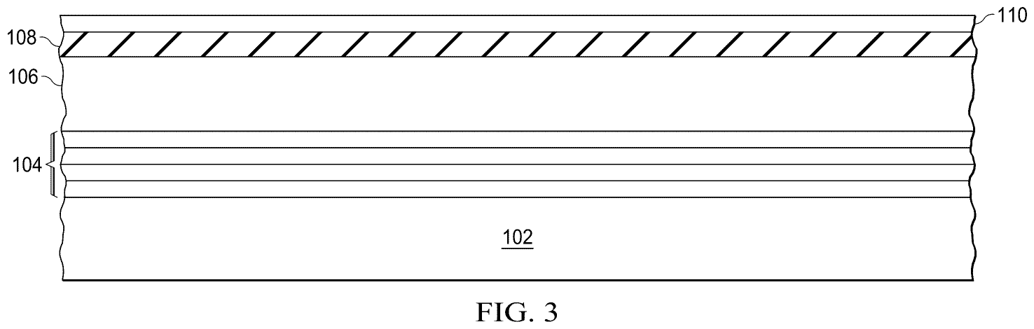

FIG. 3 through FIG. 9 are respective cross-sectional views of a semiconductor device in intermediate stages of manufacturing according to some examples. The example illustrated by FIGS. 3 through 9 shows a manufacturing method to manufacture the semiconductor devices 100, 200 of FIGS. 1 and 2 described above.

Referring to FIG. 3, one or more transition layers 104 are formed over and on a semiconductor substrate 102. A channel layer 106 is formed over and on the transition layer(s) 104. A barrier layer 108 is formed over and on the channel layer 106. A gate layer 110 is formed over and on the barrier layer 108. In some examples, the transition layer(s) 104, channel layer 106, barrier layer 108, and gate layer 110 may be formed by using any appropriate deposition process, which may further be an epitaxial growth process. For example, the transition layer(s) 104, channel layer 106, barrier layer 108, and gate layer 110 may each be epitaxially grown using metal-organic chemical vapor deposition (MOCVD), molecular beam epitaxy (MBE), low pressure chemical vapor deposition (LPCVD), or another epitaxy process. The materials of the semiconductor substrate 102, transition layer(s) 104, channel layer 106, barrier layer 108, and gate layer 110 may be as described previously. The gate layer 110 may be doped in situ during deposition (e.g., epitaxial growth) or by implantation (e.g., ion implantation) subsequent to deposition.

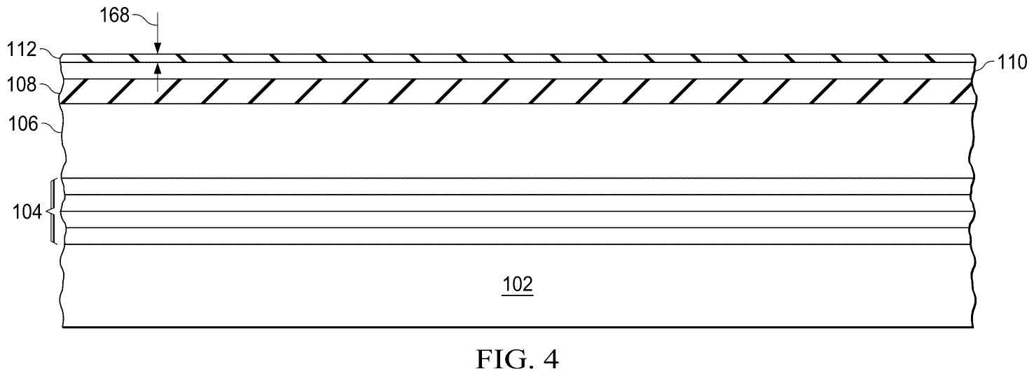

Referring to FIG. 4, an offset dielectric layer 112 is formed over and on the gate layer 110. The offset dielectric layer 112 is formed with the thickness 168, as described above. The offset dielectric layer 112 may be formed by depositing the offset dielectric layer 112 using any appropriate deposition process, such as LPCVD, plasma enhanced chemical vapor deposition (PECVD). The material of the offset dielectric layer 112 may be as described previously.

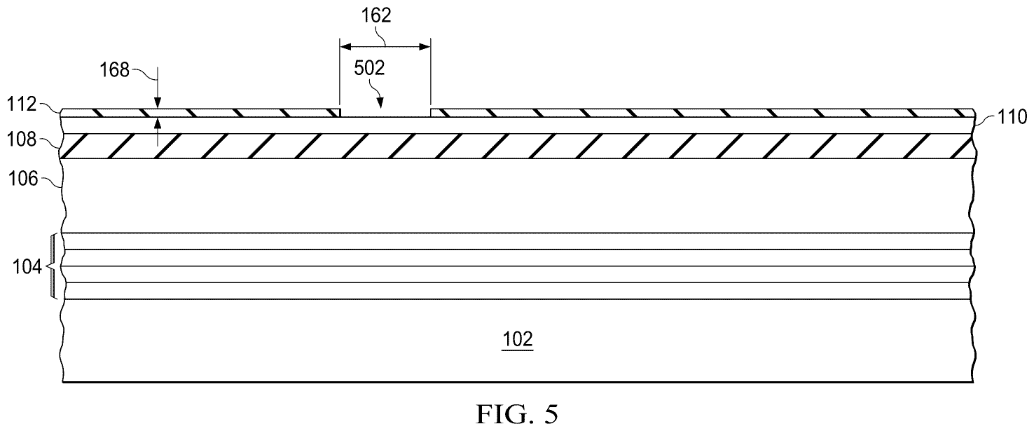

Referring to FIG. 5, a gate contact opening 502 is formed through the offset dielectric layer 112. The gate layer 110 is exposed through the gate contact opening 502 through the offset dielectric layer 112. The gate contact opening 502 has the inner lateral dimension 162, as described above. The gate contact opening 502 may be formed using appropriate photolithography and etch processes. For example, to pattern the offset dielectric layer 112 to have the gate contact opening 502, a photoresist is deposited (e.g., by spin-on) over and/or on the semiconductor substrate 102 (e.g., over and/or on the offset dielectric layer 112) and patterned using photolithography (e.g., with a photomask). The photoresist is patterned to expose an area of the offset dielectric layer 112 where the gate contact opening 502 is to be formed. Using the patterned photoresist as a mask, an etch process, such as an anisotropic etch like a reactive ion etch (RIE), is performed to form the gate contact opening 502 through the offset dielectric layer 112. After the etch process, the photoresist is removed, such as by ashing and/or a wet strip.

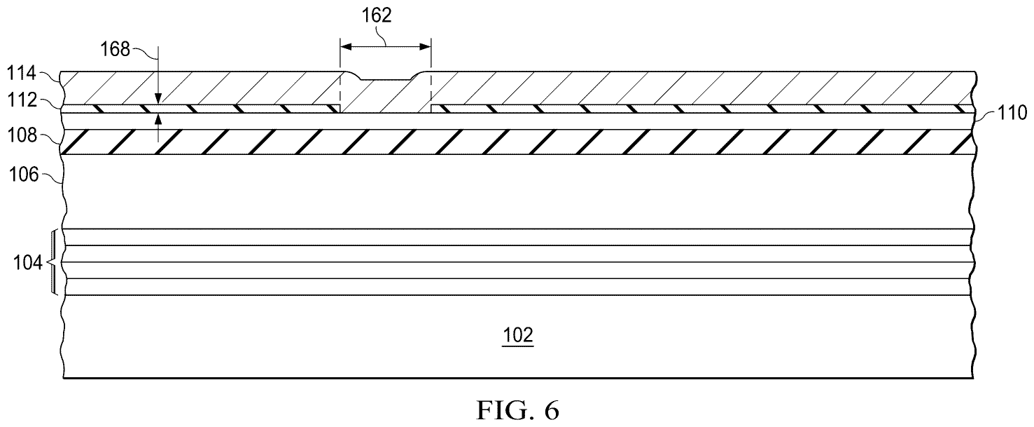

Referring to FIG. 6, a gate metal contact layer 114 is formed on and over the offset dielectric layer 112 and in the gate contact opening 502 contacting the gate layer 110. The gate metal contact layer 114 may be deposited using an appropriate deposition process(es), such as sputtering, physical vapor deposition (PVD), chemical vapor deposition (CVD), or the like. The material(s) of the gate metal contact layer 114 may be as described above with respect to the gate metal contact 114.

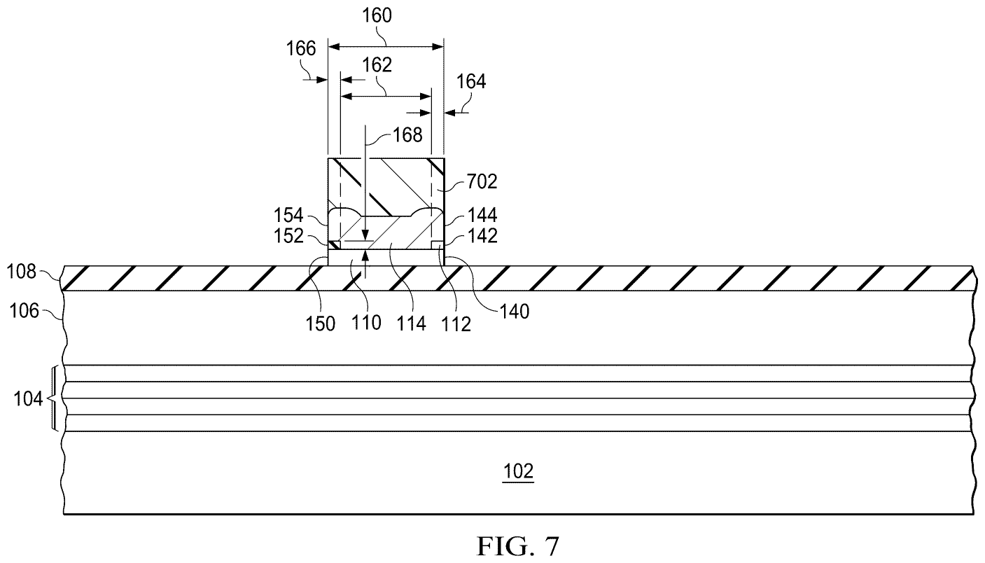

Referring to FIG. 7, the gate metal contact 114, the offset dielectric layer 112, and the gate layer 110 are patterned. Patterning of the gate metal contact 114, the offset dielectric layer 112, and the gate layer 110 in FIG. 7 forms the aligned sidewalls 140, 142, 144 and the aligned sidewalls 150, 152, 154 of the gate layer 110, the offset dielectric layer 112, and the gate metal contact 114, respectively. The gate metal contact 114, the offset dielectric layer 112, and the gate layer 110 may be patterned using a single photomask. For example, a photoresist 702 is deposited (e.g., by spin-on) over and/or on the semiconductor substrate 102 (e.g., over and/or on the gate metal contact layer 114) and patterned using photolithography (e.g., with the single photomask). The photoresist 702 is patterned to remain in an area where gate metal contact 114, the offset dielectric layer 112, and the gate layer 110 are to remain. Using the patterned photoresist 702 as a mask, an etch process, such as an anisotropic etch like an RIE, is performed to pattern the gate metal contact 114, the offset dielectric layer 112, and the gate layer 110. After the etch process, the photoresist 702 is removed, such as by ashing and/or a wet strip. The offset dielectric layer 112 is patterned to have the first offset lateral dimension 164 and the second offset lateral dimension 166. Misalignment between the photomask for forming the gate contact opening 502 and the photomask for patterning the gate metal contact 114, the offset dielectric layer 112, and the gate layer 110 may result in the offset lateral dimensions 164, 166 being unequal. In other examples, ideal alignment of those photomasks may result in the offset lateral dimensions 164, 166 being equal.

As illustrated by FIGS. 3 through 7, a metal stringer may be avoided by patterning the gate metal contact 114 and the gate layer 110 together (e.g., in a self-aligned process). In a non-self-aligned process, a gate layer may be patterned; a passivation layer may be deposited conformally over the patterned gate layer; and a gate metal contact may be formed over the passivation layer and through the passivation layer to the patterned gate layer. Forming the gate metal contact may include depositing a metal layer and patterning the metal layer into the gate metal contact. Patterning the metal layer in this non-self-aligned process may result in a stringer at a sidewall of the passivation layer that is along a sidewall of the patterned gate layer and/or may result in etch induced damage to the passivation layer from an over-etch when patterning the metal layer. Generally, the topography of the passivation layer resulting from the patterned gate layer may result in a metal stringer and/or etch induced damage to the passivation layer. In FIGS. 3 through 7, little to no topography exists in the gate layer 110, offset dielectric layer 112, and gate metal contact layer 114 outside of the photoresist 702 used for patterning. This lack of topography may obviate any metal stringer being formed. Further, without a metal stringer being a concern, over-etch may be avoided, which may obviate etch induced damage to any passivation layer. As illustrated, no passivation layer is present to be subjected to any over-etch when patterning the gate metal contact 114 in the illustrated example.

A metal stringer, as described, may be an electrically floating piece of metal, which may be capacitively coupled between the gate layer and the channel region. A metal stringer on a source side of a gate structure may increase gate-to-source current (I_{GS}). A metal stringer may incur charge trapping (e.g., due to hot electrons during a high drain voltage stress) since there may be no direct conductive path to discharge the trapped charge. The charge trapping may induce undesirable instabilities, such as dynamic R_{DSON} and dynamic threshold voltage (Vₜ) in, e.g., a HEMT. The trapped charge may affect an electric field. When the trapped charges are negative, the electric field may be decreased and may deplete the channel region, which may result in a higher R_{DSON}. When the trapped charges are positive, the electric field may be increased, which may cause the time-dependent dielectric breakdown (TDDB) to decrease. As described above, examples may avoid such a metal stringer, and hence, may have improved R_{DSON} and TDDB.

In a non-self-aligned process described above, an over-etch when patterning the gate metal contact may be implemented to remove any metal stringer. Such an over-etch may result in etch-induced damage to the underlying passivation layer. The etch-induced damage to the passivation layer may result in a thinner passivation layer, which may result in decreased TDDB. As shown in FIGS. 3 through 7, no similar passivation layer is present to be subjected to an over-etch when the gate metal contact 114 is patterned. Hence, examples may have increased TDDB.

The offset dielectric layer 112 provides an offset from the lateral outer edges of the gate layer 110 where the gate metal contact 114 does not directly contact the gate layer 110. This may reduce gate leakage, particularly, when the gate is positively forward biased. The offset dielectric layer 112 may provide such an offset to avoid an etch to shrink a gate metal contact that would expose the upper surface of the gate layer in the offset. Exposure of the upper surface of the gate layer, and further, a sidewall of the gate layer, to such an etch may damage the exposed surfaces of the gate layer, which may increase gate leakage, lower a gate breakdown voltage, and induce dynamic R_{DSON} and Vₜ shifts. Implementing the offset dielectric layer 112 may avoid these issues.

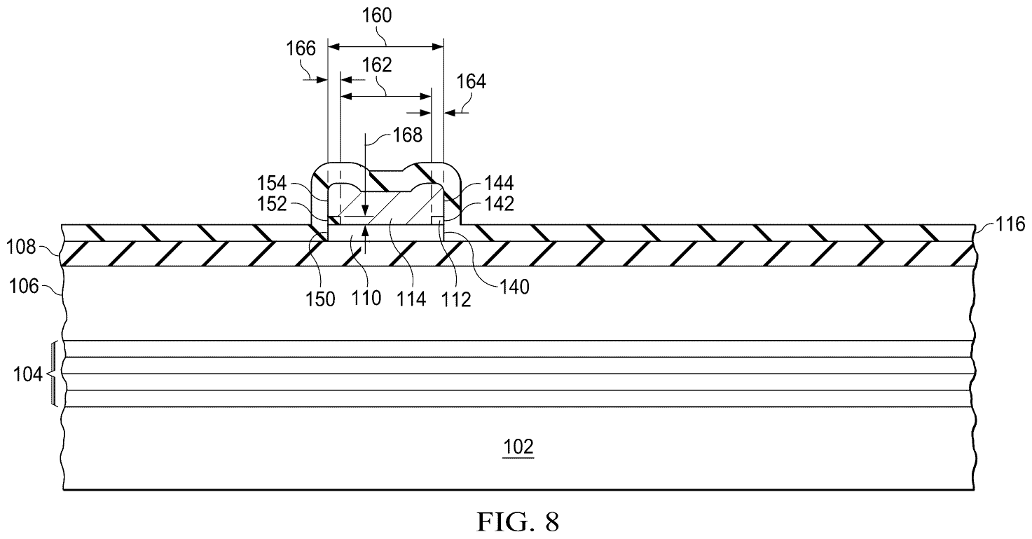

Referring to FIG. 8, a passivation layer 116 is formed conformally on and over the barrier layer 108, on and along the sidewalls 140, 150, 142, 152, 144, 154, and on and over the gate metal contact 114. The a passivation layer 116 may be deposited using any appropriate deposition process, such as LPCVD, PECVD, atomic layer deposition (ALD), or the like. The material(s) of the a passivation layer 116 may be as described above.

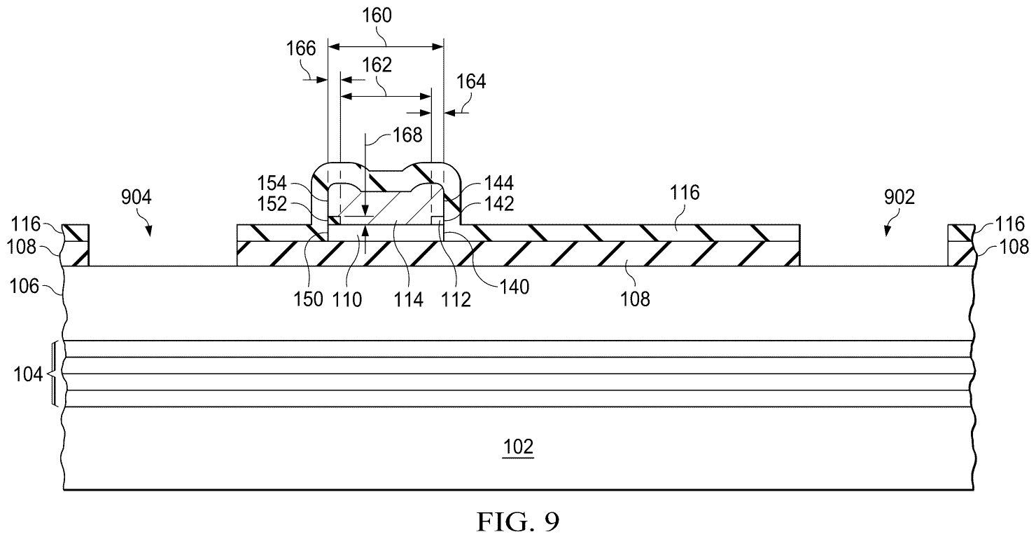

Referring to FIG. 9, a drain contact opening 902 and a source contact opening 904 are formed through the passivation layer 116. As illustrated, the drain contact opening 902 and the source contact opening 904 may also be formed through the barrier layer 108. The drain contact opening 902 and the source contact opening 904 may be formed using appropriate photolithography and etch processes. For example, to pattern the passivation layer 116, and if implemented, the barrier layer 108, to have the drain contact opening 902 and the source contact opening 904, a photoresist is deposited (e.g., by spin-on) over and/or on the semiconductor substrate 102 (e.g., over and/or on the passivation layer 116) and patterned using photolithography (e.g., with a photomask). The photoresist is patterned to expose areas of the passivation layer 116 where the drain contact opening 902 and the source contact opening 904 are to be formed. Using the patterned photoresist as a mask, an etch process, such as an anisotropic etch like an RIE, is performed to form the drain contact opening 902 and the source contact opening 904 through the passivation layer 116, and if implemented, into or through the barrier layer 108. After the etch process, the photoresist is removed, such as by ashing and/or a wet strip.

Referring to FIGS. 1 and 2, a drain metal contact 118, a source metal contact 120, and, where implemented, a source-coupled field plate 220 are formed. The drain metal contact 118 is formed in the drain contact opening 902 and partially over the passivation layer 116. The source metal contact 120 is formed in the source contact opening 904 and partially over the passivation layer 116. If implemented, the source-coupled field plate 220 is formed over the passivation layer 116 extending laterally from the source metal contact 120, over the gate metal contact 114, and from the gate metal contact 114 towards the drain metal contact 118. One or more metals are deposited into the drain contact opening 902 and the source contact opening 904 and over and on the passivation layer 116. The metal(s) may be deposited using an appropriate deposition process(es), such as sputtering, PVD, CVD, or the like. In some examples, the metal(s) may be respective conformal layer(s) in the drain contact opening 902 and the source contact opening 904 that do not fill the drain contact opening 902 and the source contact opening 904, and in some examples, the metal(s) may fill the drain contact opening 902 and the source contact opening 904. The metal(s) over the upper surface of the passivation layer 116 are patterned into the portions of the drain metal contact 118, the source metal contact 120, and, where implemented, the source-coupled field plate 220 on the upper surface of the passivation layer 116. The metal(s) may be patterned using appropriate photolithography and etch processes.

A dielectric layer 122 is formed over and on the passivation layer 116, the drain metal contact 118, and the source metal contact 120. The dielectric layer 122 may be deposited using any appropriate deposition process, such as PECVD or the like. The dielectric layer 122 may be any material described above with respect to the dielectric layer 122. The dielectric layer 122 may be planarized, such as by a chemical mechanical polish (CMP).

Metal vias 124, 126 are formed through the dielectric layer 122, and metal lines 128, 130 are formed over and on the dielectric layer 122. Via openings may be formed through the dielectric layer 122 to respective metal contacts 118, 120 using appropriate photolithography and etching processes. A metal(s) of the metal vias 124, 126 and metal lines 128, 130 are deposited over the dielectric layer 122 and in the via openings. The metal(s) may be deposited using an appropriate deposition process(es), such as CVD, PVD, or the like. The metal(s) may be patterned into the metal lines 128, 130 using appropriate photolithography and etching processes. The metal(s) underlying the metal lines 128, 130 and in the respective via openings through the dielectric layer 122 form the metal vias 124, 126.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a semiconductor gate layer over the semiconductor substrate;
an offset dielectric layer over the semiconductor gate layer; and
a gate metal contact over the offset dielectric layer and through an opening through the offset dielectric layer, the gate metal contact contacting the semiconductor gate layer through the opening through the offset dielectric layer, wherein a first sidewall of the semiconductor gate layer, a second sidewall of the offset dielectric layer, and a third sidewall of the gate metal contact are vertically aligned over the semiconductor substrate.

2. The semiconductor device of claim 1, further comprising:
a channel layer over the semiconductor substrate;
a barrier layer over the channel layer, the semiconductor gate layer being over the barrier layer;
a drain metal contact electrically coupled to a drain region in the channel layer; and
a source metal contact electrically coupled to a source region in the channel layer.

3. The semiconductor device of claim 1, wherein:
the semiconductor gate layer is a component of a transistor;
a fourth sidewall of the semiconductor gate layer, a fifth sidewall of the offset dielectric layer, and a sixth sidewall of the gate metal contact are vertically aligned over the semiconductor substrate;
the first sidewall, the second sidewall, and the third sidewall are on a drain side of the semiconductor gate layer, the offset dielectric layer, and the gate metal contact, respectively; and
the fourth sidewall, the fifth sidewall, and the sixth sidewall are on a source side of the semiconductor gate layer, the offset dielectric layer, and the gate metal contact, respectively.

4. The semiconductor device of claim 1, wherein:
the semiconductor gate layer is a component of a transistor, the transistor including a drain region and a source region;
the semiconductor gate layer has an outer lateral dimension parallel to a direction from the drain region to the source region, the outer lateral dimension being in a range from 100 nm to 3,000 nm; and
the offset dielectric layer has an offset lateral dimension from the second sidewall of the offset dielectric layer to a corresponding sidewall of the opening, the offset lateral dimension being parallel to the direction from the drain region to the source region, the offset lateral dimension being in a range from 10 nm to 500 nm.

5. The semiconductor device of claim 1, further comprising a passivation layer on the first sidewall, the second sidewall, and the third sidewall and over the gate metal contact.

6. The semiconductor device of claim 5, further comprising a metal field plate over the passivation layer, wherein the semiconductor gate layer is a component of a transistor, the transistor including a drain region, the metal field plate extending from over the semiconductor gate layer laterally towards the drain region.

7. The semiconductor device of claim 6, wherein the transistor further includes a source region, the metal field plate being electrically connected to the source region.

8. A semiconductor device, comprising:
a high electron mobility transistor (HEMT) on a semiconductor substrate, the HEMT including:
a semiconductor gate layer over a barrier layer over the semiconductor substrate;
an offset dielectric layer over the semiconductor gate layer, the offset dielectric layer having an opening to the semiconductor gate layer; and
a gate metal contact on the offset dielectric layer and in the opening contacting the semiconductor gate layer, wherein a first sidewall of the semiconductor gate layer, a second sidewall of the offset dielectric layer, and a third sidewall of the gate metal contact are vertically aligned over the semiconductor substrate.

9. The semiconductor device of claim 8, wherein:
a fourth sidewall of the semiconductor gate layer, a fifth sidewall of the offset dielectric layer, and a sixth sidewall of the gate metal contact are vertically aligned over the semiconductor substrate;
the first sidewall, the second sidewall, and the third sidewall are on a drain side of the semiconductor gate layer, the offset dielectric layer, and the gate metal contact, respectively; and
the fourth sidewall, the fifth sidewall, and the sixth sidewall are on a source side of the semiconductor gate layer, the offset dielectric layer, and the gate metal contact, respectively.

10. The semiconductor device of claim 8, wherein:
the semiconductor gate layer has an outer lateral dimension parallel to a direction from a drain region of the HEMT to a source region of the HEMT, the outer lateral dimension being in a range from 100 nm to 3,000 nm; and
the offset dielectric layer has an offset lateral dimension from the second sidewall of the offset dielectric layer to a corresponding sidewall of the opening, the offset lateral dimension being parallel to the direction from the drain region of the HEMT to the source region of the HEMT, the offset lateral dimension being in a range from 10 nm to 500 nm.

11. The semiconductor device of claim 8, wherein the HEMT further includes a passivation layer on the first sidewall, the second sidewall, and the third sidewall and over the gate metal contact.

12. The semiconductor device of claim 11, wherein the HEMT further includes a field plate over the passivation layer, the field plate extending at least laterally from the semiconductor gate layer towards a drain region of the HEMT.

13. The semiconductor device of claim 11, wherein the HEMT further includes:
a drain metal contact electrically coupled to a drain region of the HEMT, the drain metal contact being through the passivation layer; and
a source metal contact electrically coupled to a source region of the HEMT, the source metal contact being through the passivation layer.

14. The semiconductor device of claim 13, wherein the HEMT further includes a field plate over the passivation layer, the field plate extending at least laterally from the semiconductor gate layer towards the drain metal contact.

15. The semiconductor device of claim 14, wherein the field plate is electrically connected to the source metal contact.

16. The semiconductor device of claim 8, wherein the HEMT further includes:
a channel layer over the semiconductor substrate, the channel layer including a source region and a drain region;
the barrier layer over the channel layer, the semiconductor gate layer being over the barrier layer and laterally between the source region and the drain region;
a passivation layer over the barrier layer, on the first sidewall, the second sidewall, and the third sidewall, and over the gate metal contact;
a drain metal contact through the passivation layer and electrically coupled to the drain region; and
a source metal contact through the passivation layer and electrically coupled to the source region.

17. The semiconductor device of claim 16, wherein:
the channel layer includes indium aluminum gallium nitride (InᵢAlⱼGa₁₋ᵢ₋ⱼN), wherein 0≤i≤1, 0≤j≤1, and 0≤i+j≤1;
the barrier layer includes indium aluminum gallium nitride (InₖAlₗGa₁₋ₖ₋ₗN), wherein 0≤k≤1, 0≤l≤1, and 0≤k+l≤1; and
the semiconductor gate layer includes p-doped gallium nitride.

18. A method, comprising:
forming a semiconductor gate layer over a semiconductor substrate;
forming an offset dielectric layer over the semiconductor gate layer, the offset dielectric layer having an opening exposing the semiconductor gate layer;
forming a gate metal contact layer over the offset dielectric layer and on the semiconductor gate layer through the opening; and
after forming the gate metal contact layer, patterning the gate metal contact layer, the offset dielectric layer, and the semiconductor gate layer.

19. The method of claim 18, wherein patterning the gate metal contact layer, the offset dielectric layer, and the semiconductor gate layer forms a first sidewall of the gate metal contact layer, a second sidewall of the offset dielectric layer, and a third sidewall of the semiconductor gate layer, the first sidewall, the second sidewall, and the third sidewall being vertically aligned.

20. The method of claim 19, further comprising forming a passivation layer on the first sidewall, the second sidewall, and the third sidewall and over the patterned gate metal contact layer.

21. The method of claim 18, wherein patterning the gate metal contact layer, the offset dielectric layer, and the semiconductor gate layer uses a single photomask.

22. The method of claim 18, wherein after patterning the gate metal contact layer, the offset dielectric layer, and the semiconductor gate layer:
the semiconductor gate layer has an outer lateral dimension in a range from 100 nm to 3,000 nm; and
the offset dielectric layer has an offset lateral dimension in a range from 10 nm to 500 nm.
